(19) United States
(12) Patent Application Publication
(10) Pub. No.: US 2014/0264434 A1
(43) Pub. Date: Sep. 18, 2014

(54) MONOLITHIC IGNITION INSULATED-GATE BIPOLAR TRANSISTOR

(71) Applicant: Fairchild Semiconductor Corporation, San Jose, CA (US)

(72) Inventors: Joseph A. YEDINAK, Mountain Top, PA (US); Dwayne S. REICHL, Pocono Lake, PA (US); Donald Burton, Forty Fort, PA (US)

(73) Assignee: Fairchild Semiconductor Corporation, San Jose, CA (US)

(21) Appl. No.: 14/212,682

(22) Filed: Mar. 14, 2014

Related U.S. Application Data
(60) Provisional application No. 61/801,136, filed on Mar. 15, 2013.

(51) Int. Cl. F23Q 3/00; H01L 29/739; H01L 27/06

(52) U.S. Cl. CPC F23Q 3/004; H01L 27/0629; H01L 29/7393
USPC 257/140

(57) ABSTRACT

In a general aspect, an apparatus can include an insulated-gate bipolar transistor (IGBT) device disposed in a semiconductor region. The apparatus can further include a plurality of clamping diodes. The plurality of clamping diodes can be coupled in series between a collector terminal of the IGBT device and a gate terminal of the IGBT device. The apparatus can also include a gate pad disposed over at least a portion of the plurality of clamping diodes. The at least a portion of the plurality of clamping diodes can be configured, during operation of the apparatus, to have a voltage of at least 120 V applied across them.

### TECHNICAL FIELD

This description relates to insulated-gate bipolar transistors (IGBTs). In particular, the description relates to monolithic IGBT circuits that can be used in high-voltage applications, such as automotive engine ignition systems.

### BACKGROUND

Insulated-gate bipolar transistor (IGBT) devices are commonly used in high voltage applications, such as automotive ignition systems. For instance, IGBT devices may be used as coil drivers for ignition control systems. In such applications, because IGBT devices have high input impedance, they may work/integrate well with Engine Control Module (ECM) integrated circuits (ICs), which are often implemented using complementary metal-oxide semiconductor processes.

IGBT devices are also well suited for such applications, as they are capable of blocking high voltages used in automotive ignition systems and have a relatively low conduction variation over the range of temperatures that may be present in an automotive environment. (e.g., such as a temperate range of −40 to 150° C.).

### SUMMARY

In a general aspect, an apparatus can include an insulated-gate bipolar transistor (IGBT) device disposed in a semiconductor region. The apparatus can further include a plurality of clamping diodes, where the plurality of clamping diodes are coupled in series between a collector terminal of the IGBT device and a gate terminal of the IGBT device. The apparatus can also include a gate pad disposed over at least a portion of the plurality of clamping diodes, where the at least a portion of the plurality of clamping diodes are configured, during operation of the apparatus, to have a voltage of at least 120 V applied across them.

Implementations can include one or more of the following features. For example, the apparatus can include a nitride layer disposed on the plurality of clamping diodes and a dielectric layer disposed on the nitride layer, the gate pad being disposed on the dielectric layer. The apparatus can include a nitride layer disposed on the plurality of clamping diodes, where the nitride layer can have a thickness of at least 1000 angstroms. The apparatus can include a dielectric layer disposed on the nitride layer, where the dielectric layer can have a thickness of at least 900 nm. The gate pad can be disposed on the dielectric layer.

The plurality of clamping diodes, during operation of the apparatus, can be configured to have a voltage of at least 400 V applied across them. The plurality of clamping diodes can be arranged in pairs, each pair having a common anode. The plurality of clamping diodes can be arranged in pairs, each pair having a common cathode. A portion of the plurality of clamping diodes can be electrically shorted.

Each clamping diode of the plurality of clamping diodes can include an anode defined by a stripe of p-doped polysilicon and a cathode defined by a stripe of n-doped polysilicon. The plurality of clamping diodes can be formed in a single polysilicon layer. The apparatus can include a termination structure disposed around the IGBT device.

The semiconductor region can include silicon carbide (SiC).

In another general aspect, an apparatus can include an insulated-gate bipolar transistor (IGBT) device disposed in a semiconductor region. The apparatus can further include at least 10 clamping diodes. The at least 10 clamping diodes can be arranged in back-to-back pairs having common anodes. The back-to-back pairs can be coupled in series between a collector terminal of the IGBT device and a gate terminal of the IGBT device, such that adjacent pairs have common cathodes. The apparatus can also include a gate pad disposed over at least a portion of the back-to-back pairs of clamping diodes.

Implementations can include one or more of the following features. For example, each clamping diode can include an anode defined by a stripe of p-doped polysilicon and a cathode defined by a stripe of n-doped polysilicon. The at least 10 clamping diodes can be formed in a single polysilicon layer.

The semiconductor region can include silicon carbide (SiC). The apparatus can include a termination structure disposed around the IGBT device. A portion of the plurality of clamping diodes can be electrically shorted.

In another general aspect, an apparatus can include an insulated-gate bipolar transistor (IGBT) device disposed in a semiconductor region. The apparatus can further include at least 10 clamping diodes. The at least 10 clamping diodes can be arranged in back-to-back pairs having common cathodes. The back-to-back pairs can be coupled in series between a collector terminal of the IGBT device and a gate terminal of the IGBT device, such that adjacent pairs have common anodes. The apparatus can also include a gate pad disposed over at least a portion of the back-to-back pairs of clamping diodes.

Implementations can include one or more of the following features. For example, each clamping diode can include an anode defined by a stripe of p-doped polysilicon and a cathode defined by a stripe of n-doped polysilicon. The at least 10 clamping diodes can be formed in a single polysilicon layer.

The semiconductor region can include silicon carbide (SiC). The apparatus can include a termination structure disposed around the IGBT device. A portion of the plurality of clamping diodes can be electrically shorted.

### BRIEF DESCRIPTION OF THE DRAWINGS

FIG. 1 is a circuit schematic diagram that illustrates an ignition circuit including a monolithic insulated-gate bipolar transistor (IGBT) circuit, according to an embodiment.

FIG. 2 is diagram that illustrates a plan view of a monolithic IGBT circuit (with a gate pad disposed over a portion of a clamp) that may be included in the ignition circuit of FIG. 1, according to an embodiment.

FIG. 3 is a diagram illustrating a semiconductor process mask overlay of a portion of a monolithic IGBT circuit, such as the circuit of FIG. 2, according to an implementation.

FIG. 4 is a diagram illustrating a cross-sectional view of the monolithic IGBT circuit of FIG. 3, according to an implementation.

Like reference symbols in the various drawings indicate like and/or similar elements.

### DETAILED DESCRIPTION

IGBT devices for use in such high voltage applications, such as those described herein, may be integrated/implemented in a circuit that includes a number of circuit components that are formed on a single semiconductor substrate, where at least some of those circuit components may be formed using polysilicon (gate) material. For instance, these circuit components may include a series string of back to back polysilicon diodes, where the diodes are configured to provide active clamping for high voltages, e.g., in an automotive ignition application.

Gate pads that are used to provide a connection to a gate terminal of an IGBT in such circuits can be placed over a ground plane (generally diffusion that forms, at least part, of an emitter of the IGBT). This approach results in a significant amount of semiconductor area being used that does not include any “active” elements of the circuit (other than emitter diffusion). However, approaches that make more efficient use of the amount of semiconductor substrate used to manufacture such ignition IGBT devices may be implemented using the approaches described herein.

FIG. 1 is a circuit schematic diagram that illustrates an ignition circuit 100 including a monolithic insulated-gate bipolar transistor (IGBT) circuit (IGBT circuit) 110, according to an embodiment. The ignition circuit 100 is shown by way of example as one possible application for a monolithic IGBT circuit, such as the monolithic IGBT circuit 110 shown in FIG. 1. In other embodiments, other arrangements of the ignition circuit 100 and the IGBT circuit 110 are possible. Further, such monolithic IGBT circuits may be used in other applications.

As shown in FIG. 1, the ignition circuit 100 also includes a control circuit 150, an ignition coil 160 and a spark plug 170 (e.g., such as may be used in an internal combustion engine). In some implementations, the control circuit 150 may be an engine control module (ECM) circuit, such as a microcontroller, for example. In other implementations, the control circuit 150 may include a driver circuit that is configured to provide a control signal (or signals) to the monolithic IGBT circuit 110.

In the ignition circuit 100, the control signal(s) from the control circuit 150 may be received at a gate terminal of an IGBT device 115 that is included in the monolithic IGBT circuit 110. In response to the control signal(s), the IGBT device 115 may drive a primary winding 162 of the ignition coil 160 to control firing of the spark plug 170. For instance, the IGBT device 115 driving the primary winding 162 of the ignition coil 160 (e.g., in response to a control signal) may result in corresponding charging and discharging of a secondary winding 164 of the ignition coil 160. Such charging and discharging in the secondary winding 164 of the ignition coil 164 may then result in current being shunted through the spark plug 170, causing the spark plug 170 to “fire” or “spark”, e.g., so as to ignite a fuel mixture in an internal combustion engine cylinder.

As shown in FIG. 1, the IGBT circuit 110 includes a plurality of clamping diodes 120, a first set of electrostatic discharge (ESD) protection diodes 125, a second set of ESD protection diodes 130, a first resistor 135 and a second resistor 140. The clamping diodes 120 may operate to clamp a high voltage potential that is applied to the IGBT circuit 110 by the primary winding 162 of the ignition coil 160. For instance, the string of clamping diodes 120 may be configured to actively clamp a voltage potential that is applied to a collector terminal (which may also be referred to as a drain terminal) of the IGBT device 115. In such an approach, the clamping diodes 120 may feed a small amount of a collector current (from the IGBT device 115) back to the gate terminal of the IGBT device 115 (e.g., when the clamping diodes 120 break down). This current feedback may allow for the IGBT to operate in a liner mode under gate control, which may further allow for precise control (e.g., +/−10%) of a clamping voltage of the ignition circuit 100. In turn, precise control of the clamping voltage may allow for similarly precise control of an amount of energy that is delivered over a specified time period to the spark plug 170 for each spark occurrence.

Further, in the ignition circuit 100, the resistor 135 may operate so as to limit a gate current for the IGBT device 115 and the resistor 140 may operate so as to regulate a gate voltage for IGBT 140. The values of the resistors 135,140 may depend on the specific implementation, such as based on the configuration of the control circuit 150 and/or the gate rating (voltage and/or current rating) of the gate of the IGBT device 115. As also shown in FIG. 1, one terminal of the spark plug 170 and one terminal of the secondary winding 164 may be commonly coupled to an electrical ground. Further an emitter terminal (which may also be referred to as a source terminal) of the IGBT device 115, a terminal of the resistor 140 and one cathode terminal of each of the ESD diodes 125,130 are commonly coupled to an electrical ground (e.g., via a ground terminal of the IGBT circuit 110). Depending on the particular implementation, the two electrical grounds shown in FIG. 1 may be a common electrical ground, or may be separately established.

As shown in FIG. 1, the clamping diodes 120, the ESD diodes 125 and the ESD diodes 130 may be implemented using “back-to-back” diode pairs, where each back-to-back pair of diodes (diode pair) has a common anode node. While only two clamping diode pairs 120 are shown in FIG. 1, in other implementations, the IGBT circuit 110 may include a number of additional pairs of clamping diodes 120. For instance, in one implementation, the IGBT circuit 110 may include fifty-six (56) diode pairs (with a total of 112 individual diodes). In such an approach, the IGBT circuit 110 may operate with a clamping voltage of approximately 400 V (approximately 7 V per diode pair). In other implementations, fewer or additional clamping diode pairs 120 may be used. For instance, the IGBT circuit 110 may include 10 or more clamping diode pairs, 20 or more clamping diode pairs, 30 or more clamping diode pairs 120, 40 or more clamping diode pairs 120, 50 or more clamping diode pairs, and so on. The number of clamping diodes used may be based on the desired clamping voltage for a particular implementation. In other implementations, back-to-back clamping diodes 120 with common cathode nodes may be used, and/or back-to-back clamping diodes 120 with common cathode nodes of adjacent diodes and common anode nodes of adjacent diodes may be used.

As also shown in FIG. 1, the clamping diode pairs 120 may be connected in series (electrically in series) with each other between the collector terminal and the gate terminal of the IGBT device 115. As illustrated in FIG. 1, electrically adjacent clamping diode pairs 120 may have a common (electrically and/or physically common) anode node.

In similar fashion as the clamping diodes 120, while only a single diode pair (with a common anode node) is shown in FIG. 1 for each of the ESD diodes 125,130, in other implementations, the ESD diodes 125,130 may include additional diode pairs. For instance, in one implementation, the ESD diodes 125 and/or the ESD diodes 130 may include two diode pairs. In another implementation, the ESD diodes 125 and/or the ESD diodes 130 may include three diode pairs. In still other implementation, the ESD diodes 125,130 may include other numbers of diode pairs. The number of diode pairs used to implement the ESD diodes 125,130 will depend on the particular implementation. For instance the number of ESD diode pairs used may depend on a voltage rating (breakdown voltage) for the gate of the IGBT device 115, where the breakdown voltage of the ESD diodes 125,130 is set to be between an operating gate voltage of the IGBT 115 and the voltage rating of the gate of the IGBT 115. In approaches including multiple ESD diode pairs, in like fashion as discussed above for the clamping diode pairs 120, electrically adjacent ESD diode pairs 125,130 may have a common anode node and/or a common cathode node.

FIG. 2 is diagram that illustrates a plan view of a monolithic IGBT circuit, according to an embodiment. In certain embodiments, the IGBT circuit shown in FIG. 2 may be used to implement the IGBT circuit 110 of the ignition circuit 100 illustrated in FIG. 1. Accordingly, the IGBT circuit shown in FIG. 2 is likewise referenced as IGBT circuit 110, and the elements of the IGBT circuit 110 in FIG. 2 are referenced with like reference numbers as their corresponding elements in FIG. 1.

As illustrated in FIG. 2, the IGBT circuit 110 may be integrated (monolithically) on a single semiconductor substrate, such as in the implementations illustrated in FIGS. 3 and 4, and discussed in further detail below. In the IGBT circuit 110 of FIG. 2, the IGBT device (IGBT) 115 is shown as being substantially U-shaped, having narrow portions on the left side and the right side in an upper portion of the IGBT circuit 110 (as illustrated in FIG. 2) and a wider portion (substantially the width of the IGBT circuit 110) in a lower portion of the IGBT circuit 110.

As illustrated in FIG. 2, the IGBT 115 may be surrounded (substantially surrounded) with one or more termination structures (termination structure) 200. The termination structure 200 may take a number of forms and the exact configuration may depend on the specific embodiment. For instance, the termination structure 200 may include an equal potential ring (e.g., formed using polysilicon, diffusion and/or one or more implant regions) disposed around the IGBT 115.

The IGBT circuit 110 shown in FIG. 2 also includes the clamping diodes 120 and the ESD diodes 125,130 of FIG. 1, which are all disposed in the upper portion of the IGBT circuit 110 between the narrow portions of the IGBT 115 and outside the termination structure 200. The particular arrangement of the IGBT device 115, the termination structure 200, the clamping diodes 120 and the ESD diodes 125,130 is given by way of example and for purposes of illustration. In other implementations, other arrangements are possible. Further, the elements shown in FIG. 2 may not be drawn to scale and their actual sizes, and relative sizes, may vary based on the specific implementation.

As shown in FIG. 2, the IGBT circuit 110 also includes a gate pad 210 that is disposed over at least a portion of the clamping diodes 120. The gate pate 210 may be used, for example, to establish an electrical connection between the gate terminal of the IGBT 115 and the control circuit 150 of the ignition control circuit 100 shown in FIG. 1. For instance, a solder ball (not shown) may be disposed on the gate pad 210 and that solder ball may be use to electrically couple the IGBT circuit 110 to a signal line used to communicate a control signal (or signals) from the control circuit 150 to the IGBT circuit 110 (e.g., to the gate terminal of the IGBT 115).

In the IGBT circuit 110, disposing the gate pad 210 over the clamping diodes 120 (e.g., at least a portion of the clamping diodes 120) may provide a number of potential benefits over previous approaches that have a gate pad disposed over a ground plane (e.g., diffusion that is electrically coupled with an emitter terminal of the IGBT 115). For example, an area of a semiconductor substrate (on which the IGBT circuit 110 is implemented) that was previously used to form the ground plane under the gate pad may be, instead, used to form additional active area of the IGBT 115. This increase in active area may result in a corresponding increase in a current rating and/or a voltage rating of the IGBT 115 in the IGBT circuit 110. Alternatively, the substrate area that was previously used to form the ground plane under the gate pad can be eliminated, which may allow for using a reduced die size (overall semiconductor substrate area) for the IGBT circuit 110. This reduced die size may reduce manufacturing cost.

FIG. 3 is a diagram illustrating a semiconductor process mask overlay 300 that corresponds with a portion of a monolithic IGBT circuit, such as a portion of the IGBT circuit 110 of FIG. 2 (and the associated circuit in FIG. 1), according to an implementation. In FIG. 3, the mask overlay 300 corresponds with a portion of an example implementation of the IGBT circuits 110 of FIGS. 1 and 2 that includes the clamping diodes 120, the ESD diodes 130 as well as number of other elements that may be included in such a monolithic IGBT circuit. Accordingly, FIG. 3 is described with further reference (and interchangeably) with the IGBT circuits 110 illustrated in FIGS. 1 and 2, using like reference numbers as in FIGS. 1 and 2.

In FIG. 3, elements of a monolithic IGBT circuit, such as the circuit 110, are represented using digitized masking layers in the mask overlay 300. In the mask overlay 300, some of the masking layers are implemented as “exclude” masking layers and, as a result, shading for some elements in FIG. 3 varies in the mask overlay 300. For instance, in FIG. 3, a metal masking layer that digitizes where metal is not wanted is used. Therefore, in the mask overlay 300, the digitized metal layer represents areas where metal is desired as open areas, which results, at least in part, in the shading differences for some elements of the illustrated monolithic IGBT circuit in the mask overlay 300. As an example, the area where the gate pad 210 is disposed is indicated with a dashed line that indicates the (approximate) locations of the edges of the gate pad 210. As illustrated in FIG. 3, the gate pad 210 area is shown as an open area that is surrounded by a digitized layer that indicates where metal will be removed (excluded), such as by a semiconductor process masking and etch operation that may be performed after depositing a continuous layer of metal on a semiconductor substrate used to implement the IGBT circuit 110. As a result, the shading for a digitized layer representing polysilicon in the mask overlay 300 varies from where metal is present (e.g., polysilicon shown in black for n+ stripes) to where metal is not present (e.g., polysilicon shown in gray for n+ stripes).

The clamping diodes 120 are arranged in three groups in the mask overlay 300. In this example, the clamping diodes are illustrated as alternating stripes of p+ polysilicon (e.g., white stripes) and stripes of n+ polysilicon (e.g., black/gray stripes). In an IGBT circuit 110 implemented using the masking overlay 300, relatively larger n+ polysilicon regions 310a, 310b, 310c are disposed between the groups of clamping diodes 120. The n+ polysilicon regions 310a, 310b, 310c may operate (in like manner as the n+ stripes), electrically, as common cathodes for the clamping diodes 120 whose anodes are disposed at the end of each group and between adjacent groups of clamping diodes 120. In the IGBT circuit 110, these common cathodes may be used as intermediate biasing points for the clamping diodes 120, and/or may be connected with and form, at least a part of, the termination structure 200.

In this example, an IGBT circuit 110 produced using the masking overlay 300 may include 56 clamping diode pairs 120 (32 pairs in the top group, 14 in the middle group and 10 in the bottom group), for a total of 112 individual diodes. In an implementation, the clamping diodes 120 (and the ESD diodes 125,130) may be formed by first performing a blanket p+ implant (and/or performing in-situ doping) on a polysilicon layer and then the forming the n+ stripes using a masking layer to define the locations of the n+ stripes. After defining the locations of the n+ stripe, an n+ counter-doping of the previously p+ doped polysilicon may be performed in the locations of the n+ stripes. In certain embodiments, other polysilicon circuit features of the IGBT circuit 110 may be doped concurrently with the clamping diodes 120 and the ESD diodes 125,130.

As may be seen in FIG. 3, the gate pad 210, which may be electrically connected with the gate terminal of the IGBT device 115 using the gate pad contacts 320, is disposed over, at least part of, the two lower groups of clamping diodes 120 or, in this example, 24 clamping diode pairs 120 (e.g., 10 diode pairs in the bottom group and 14 diode pairs in the middle group). Accordingly, in operation, the clamping diodes 120 disposed under the gate pad 210 may have a voltage potential of approximately 170 V applied across the series arrangement of the 24 diode pairs in the lower two groups (approximately 7 V per diode pair). In like fashion as discussed above, the total voltage potential across all 56 clamping diode pairs 120 of the IGBT circuit 110,in this example, may be 400 V or more.

Using the mask overlay 300 may allow for easy adjustment of a clamping voltage for an associated IGBT circuit 110. For instance, the clamping voltage may be decreased by removing one or more of the (common anode) p+ polysilicon stripes (which effectively removes one diode pair of the clamping diodes 120 per p+ polysilicon stripe removed). Alternatively, the clamping voltage may be increased by adding (in the open regions between the groups of diodes) one or more (common anode) p+ polysilicon stripes (which effectively adds one diode pair of the clamping diodes 120 per p+ polysilicon stripe added).

ESD diodes 330 are also shown in FIG. 3. Depending on the specific embodiment, the ESD diodes 330 in FIG. 3 may correspond with the ESD diodes 125 and/or the ESD diodes 130 shown in FIG. 2. As illustrated in FIG. 3, the ESD diodes 330 include three pair of back-to-back diodes (e.g., have three p+ polysilicon stripes corresponding with three common anodes of three diode pairs). The masking overlay 300 can also include contacts to other terminals of the IGBT device 115 (other than the gate terminal, which was discussed above) including drain contacts 340, and emitter contacts/emitter metal 350, which may be used to electrically contact an emitter terminal of the IGBT device 115 of the IGBT circuit 110.

The mask overlay 300 may also be used to define, in the IGBT circuit 110, a junction termination extension (JTE) diffusion region that is disposed, at least partially, under the emitter metal 350 and extends under the gate contacts 320. The JTE diffusion region is not explicitly shown in FIG. 3, but is illustrated in FIG. 4 as JTE diffusion 425. Such JTE diffusion (or a ground plane beneath circuit components) may be used to spread an electric field (e.g., in an emitter of the IGBT) over a larger area in order to reduce the magnitude of field concentration. For instance, the JTE diffusion may extend laterally from a junction (the emitter junction in the IGBT device 110) to spread an applied field over a larger area, and thus increase a voltage at which avalanche breakdown may occur.

FIG. 4 is a diagram illustrating a cross-sectional view 400 of the IGBT circuit 110 corresponding with the mask overlay 300 of FIG. 3, according to an implementation. The cross-sectional view 400 corresponds with a cross section of the IGBT circuit 110 taken along the section line 360 shown in FIG. 3 when viewing the portion of the IGBT circuit 110 to the right of the section line 360 from the left side of the drawing. As shown in FIG. 4, the IGBT circuit 110 may be formed in an n-type epitaxial semiconductor region (n-epi layer) 405. The n-epi layer 405 may be disposed on an n-epi buffer layer 410 and the n-epi buffer layer 410 may be disposed on a p+ substrate 415. In FIG. 4, the edge of the die (e.g., the semiconductor material or semiconductor substrate) may be adjacent to the left edge 420 of the cross-sectional view 400, while an active area (the IGBT device 115) may begin at the (e.g., p-type) JTE diffusion 425 and extend away from the right edge 430 of the cross-sectional view 400.

As shown in FIG. 4 a field oxide layer 435 is disposed on the n-epi layer 405 (e.g., where the n-epi layer is a semiconductor region used to form the IGBT circuit 110). In certain embodiments, the field oxide layer 435 may be formed using a thermal thermally grown oxide. In other embodiments, the field oxide layer 435 may be formed using other process, such as a dielectric (oxide) deposition process and/or a local-oxidation-of-silicon (LOCOS) process. In other embodiments, other processes may be used (alone and/or in combination with one or more of the above mentioned processes) to form the field oxide layer 435. In an example embodiment, the field oxide layer may have a thickness in the range of 0.8-1.2 (micrometers) μm. In other embodiments, the field oxide layer may be thinner or thicker than the range indicated above.

As further illustrated in FIG. 4, a polysilicon layer 440, in which the p+ polysilicon stripes and the n+ polysilicon stripes of the gate-to-drain clamping diodes 120 and the ESD diodes 125,130 may be formed, such as in the manners described herein, may be disposed on the field oxide layer 435. In an example embodiment, the polysilicon layer 440 may be approximately 850 (nanometers) nm thick. In other embodiments, the polysilicon layer may be thinner or thicker than 850 nm. In FIG. 4, the left grouping of gate-to-drain clamping diodes 120 corresponds with the top grouping of 32 clamping diode pairs 120 in FIG. 3. Similarly, the middle grouping of gate-to-drain clamping diodes 120 in FIG. 4 corresponds with the middle grouping of 14 clamping diode pairs 120 in FIG. 3. Likewise, the right grouping of gate-to-drain clamping diodes 120 in FIG. 4 corresponds with the bottom grouping of 10 clamping diode pairs 120 in FIG. 3. Also, as is shown in FIG. 4, and as was described with respect to FIG. 3, the gate pad 210 is disposed over the right two groups of clamping diode pairs 120, which correspond with the 24 total clamping diode pairs 120 in the middle group and the bottom group of clamping diode pairs 120 in FIG. 3. As also shown in FIG. 4, ESD diodes 130 (corresponding with the ESD diodes 330 of FIG. 3) formed in the polysilicon layer 440 are disposed over the p-type JTE diffusion region 425.

In some implementations, a lower clamping voltage from the gate terminal to drain terminal of the IGBT 115 (as compared to the clamping voltage from the drain to gate of the IGBT) may be desired. In such implementations, one or more of the clamping diodes 120 that would normally be forward biased during a drain to gate voltage clamping operation (e.g., the diodes with gate facing cathodes) may be electrically shorted (e.g., using a conductive (metal) layer to short their anodes and cathodes). Of course, other approaches may be used such to achieve such a result, as using singular diodes where a larger number of the singular diodes have drain facing cathodes (e.g., to provide a relatively higher clamping voltage from drain to gate) than a number of the singular diodes that have gate facing cathodes (e.g., to provide a relatively lower clamping voltage from gate to drain).

As illustrated in FIG. 4, a nitride layer 445 is disposed on the polysilicon layer 440 in which the clamping diodes 120 and the ESD diodes 125,130 may be implemented. In an example embodiment, the nitride layer 445 may be approximately 1100 angstroms thick. In other embodiments, the nitride layer 445 may have a different thickness. For instance the nitride layer 445 may be 700 angstroms or more, 800 angstroms or more, 900 angstroms or more, 1000 angstroms or more, 1200 angstroms or more, and so forth. As shown, in the cross-sectional view 400, a dielectric layer 450 (e.g., a borophosphosilicate glass (BPSG) layer) may be disposed on the nitride layer 445. In certain embodiments, such a dielectric (BPSG) layer 450 may be approximately 1 μm thick. In other embodiments, other dielectric layer thicknesses may be used. For instance, in an example embodiment, a BPSG layer of 700 nm or more could be used, a BPSG layer of 800 nm or more could be used, a BPSG layer of 900 nm or more could be used, a BPSG layer of 1.1 μm or more could be used, and so forth. The thickness of the dielectric layer 450 disposed on the nitride layer 445 may depend on the specific embodiment, such as the specific material used, the voltage that is applied across the clamping diodes 120 under the gate pad 210, among a number of other possible factors.

In the embodiments described herein, arrangement of the layers disposed between the gate pad 210 and the clamping diodes 120 disposed under the gate pad 210 must be configured to tolerate the high voltages applied across the clamping diodes 120 during operation of an associated IGBT circuit 110, such as when implemented in the automotive ignition circuit 100 shown in FIG. 1. For example, the layers disposed between the gate pad 210 and the clamping diodes 120 disposed under the gate pad 210 must be configured to prevent arcing and/or voltage breakdown from the clamping diodes 120 to the gate pad (e.g., to protect the gate of the IGBT device 115 and/or protect the control circuit 150). The particular arrangement used will depend on the specific embodiment.

Other elements shown in FIG. 4 also correspond with the elements of the IGBT described above with respect to FIG. 3. For example, the drain metal/drain contact 340 in FIG. 4 corresponds with the drain contact region 340 in FIG. 3, the emitter metal 350 in FIG. 4 corresponds with the emitter metal 350 of FIG. 3 and the gate pad 210 corresponds with the gate pad 210 of FIG. 3, as were described above. Further, the cross-sectional view 400 shows the p-type JTE diffusion 425, as was previously discussed. Also shown in FIG. 4 are other diffusion regions, implant regions and polysilicon features of the IGBT circuit 110 not explicitly shown and/or described with respect to FIG. 3. These features include an n+ channel stopper implant 460, an n-type JFET diffusion 465, an n+ source diffusion 470 and a gate polysilicon (poly) 475 of the IGBT device 115, as well as other elements of an IGBT device, such as p-wells, for example.

The various apparatus and techniques described herein may be implemented using various semiconductor processing and/or packaging techniques. Some embodiments may be implemented using various types of semiconductor processing techniques associated with semiconductor substrates including, but not limited to, for example, Silicon (Si), Galium Arsenide (GaAs), Silicon Carbide (SiC), and/or so forth.

It will also be understood that when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present.

Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Although discussed in the context of an automotive application, in some implementations, the apparatus and approaches described herein can be implemented in a variety of applications, as was noted above. In other words, implementations of the various devices described herein can be included in a variety of devices or systems. The IGBT circuit 110 can be implemented in, or can be included in, for example, a laptop-type device with a traditional laptop-type form factor.

In some implementations, a device that includes the IGBT circuit 110 can be, or can include, for example, a wired device and/or a wireless device (e.g., Wi-Fi enabled device), a computing entity (e.g., a personal computing device), a server device (e.g., a web server), a mobile phone, an audio device, a motor control device, a power supply (e.g., an off-line power supply), a personal digital assistant (PDA), a tablet device, e-reader, a television, an automobile, and/or so forth. In some implementations, a device including the IGBT circuit 110 can be, or can include, for example, a display device (e.g., a liquid crystal display (LCD) monitor, for displaying information to the user), a keyboard, a pointing device (e.g., a mouse, a trackpad, by which the user can provide input to the computer).

In some implementations, a device including the IGBT circuit 110 can be, or can include, for example, a back-end component, a data server, a middleware component, an application server, a front-end component, a client computer having a graphical user interface or a Web browser through which a user can interact with an implementation, or any combination of such back-end, middleware, or front-end components. Devices including the IGBT circuit 110, such as those described herein, may be interconnected by any form or medium of digital data communication, e.g., a communication network. Examples of communication networks include a local area network (LAN) and a wide area network (WAN), e.g., the Internet.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the embodiments. It should be understood that they have been presented by way of example only, not limitation, and various changes in form and details may be made. Any portion of the apparatus and/or methods described herein may be combined in any combination, except mutually exclusive combinations. The embodiments described herein can include various combinations and/or sub-combinations of the functions, components and/or features of the different embodiments described.

What is claimed is:

1. An apparatus, comprising:
an insulated-gate bipolar transistor (IGBT) device disposed in a semiconductor region;
a plurality of clamping diodes, the plurality of clamping diodes being coupled in series between a collector terminal of the IGBT device and a gate terminal of the IGBT device;
a gate pad disposed over at least a portion of the plurality of clamping diodes, the at least a portion of the plurality of clamping diodes being configured, during operation of the apparatus, to have a voltage of at least 120 V applied across them.

2. The apparatus of claim 1, further comprising:
a nitride layer disposed on the plurality of clamping diodes; and
a dielectric layer disposed on the nitride layer, the gate pad being disposed on the dielectric layer.

3. The apparatus of claim 1, further comprising:
a nitride layer disposed on the plurality of clamping diodes, the nitride layer having a thickness of at least 1000 angstroms; and
a dielectric layer disposed on the nitride layer, the dielectric layer having a thickness of at least 900 nm, the gate pad being disposed on the dielectric layer.

4. The apparatus of claim 1, wherein the plurality of clamping diodes, during operation of the apparatus, is configured to have a voltage of at least 400 V applied across them.

5. The apparatus of claim 1, wherein the plurality of clamping diodes are arranged in pairs, each pair having a common anode.

6. The apparatus of claim 1, wherein the plurality of clamping diodes are arranged in pairs, each pair having a common cathode.

7. The apparatus of claim 1, wherein a portion of the plurality of clamping diodes are electrically shorted.

8. The apparatus of claim 1, wherein the semiconductor region includes silicon carbide (SiC).

9. The apparatus of claim 1, wherein each clamping diode of the plurality of clamping diodes includes:
an anode defined by a stripe of p-doped polysilicon; and
a cathode defined by a stripe of n-doped polysilicon, the plurality of clamping diodes being formed in a single polysilicon layer.

10. The apparatus of claim 1, further comprising a termination structure disposed around the IGBT device.

11. An apparatus, comprising:
an insulated-gate bipolar transistor (IGBT) device disposed in a semiconductor region;
at least 10 clamping diodes, the at least 10 clamping diodes being arranged in back-to-back pairs having common anodes, the back-to-back pairs being coupled in series between a collector terminal of the IGBT device and a gate terminal of the IGBT device such that adjacent pairs have common cathodes;
a gate pad disposed over at least a portion of the back-to-back pairs of clamping diodes.

12. The apparatus of claim 11, wherein each clamping diode of the at least 10 clamping diodes includes:
an anode defined by a stripe of p-doped polysilicon; and
a cathode defined by a stripe of n-doped polysilicon, the at least 10 clamping diodes being formed in a single polysilicon layer.

13. The apparatus of claim 11, wherein the semiconductor region includes silicon carbide (SiC).

14. The apparatus of claim 11, further comprising a termination structure disposed around the IGBT device.

15. The apparatus of claim 11, wherein a portion of the at least clamping diodes are electrically shorted.

16. An apparatus, comprising:
an insulated-gate bipolar transistor (IGBT) device disposed in a semiconductor region;
at least 10 clamping diodes, the at least 10 clamping diodes being arranged in back-to-back pairs having common cathodes, the back-to-back pairs being coupled in series between a collector terminal of the IGBT device and a gate terminal of the IGBT device such that adjacent pairs have common anodes;
a gate pad disposed over at least a portion of the back-to-back pairs of clamping diodes.

17. The apparatus of claim 16, wherein each clamping diode of the at least 10 clamping diodes includes:
an anode defined by a stripe of p-doped polysilicon; and
a cathode defined by a stripe of n-doped polysilicon, the at least 10 clamping diodes being formed in a single polysilicon layer.

18. The apparatus of claim 16, wherein the semiconductor region includes silicon carbide (SiC).

19. The apparatus of claim 16, further comprising a termination structure disposed around the IGBT device.

20. The apparatus of claim 16, wherein a portion of the at least 10 clamping diodes are electrically shorted.
